(19) United States
(12) Patent Application Publication
(10) Pub. No.: US 2026/0076228 A1
(43) Pub. Date: Mar. 12, 2026

(54) PRE-FABRICATED PIN-BASED VERTICAL ELECTRICAL CONNECTIVITY IN A PACKAGE SUBSTRATE

(71) Applicant: NVIDIA Corporation, Santa Clara, CA (US)

(72) Inventors: Padam Jain, San Jose, CA (US); Tony Baek, Santa Clara, CA (US); Sean Kalchuri, San Jose, CA (US)

(21) Appl. No.: 18/828,542

(22) Filed: Sep. 9, 2024

(51) Int. Cl. H01L 23/538; H01L 21/48; H01L 23/14; H01L 23/498

(52) U.S. Cl. CPC H10W 70/65; H10W 70/095; H10W 70/611; H10W 70/66; H10W 70/695; H10W 90/401

(57) ABSTRACT

A substrate is disclosed. In one embodiment, the substrate comprises a substrate core including a plurality of through holes located therethrough, a plurality of metal pins aligned in the plurality of through holes, and at least one layer deposited on at least one of top and bottom surfaces of the substrate core. In one embodiment, the plurality of metal pins are aligned with the plurality of through holes such that each of the plurality of metal pins extends at least to both the top and bottom surface of the substate core. In some embodiments, the deposited at least one layer is deposited after the plurality of metal pins have been aligned in the through holes of the substrate core.

### TECHNICAL FIELD

This application is directed to, in general, package substrate core layers and, more specifically, to pre-fabricated pin-based vertical interconnects in a package substrate core layer.

### BACKGROUND

As performance of integrated circuits (ICs) continues to increase, it is common to mount several ICs to one or both sides of a single substrate. At the core or center of the substrate is a substrate core layer (i.e., a “substrate core”) that is typically made from a glass fiber reinforced epoxy material, e.g., FR4. As die sizes continue to increase in size and the number dies that are desired to be placed on a single substrate increase, the size of the substrate core in a cartesian x-y direction must also increase. As the size of the substrate core increases in the x-y direction, the thickness of the substrate core in the z direction must increase as well to provide mechanical stability for the dies and to mitigate substrate warpage related challenges.

### SUMMARY OF THE DISCLOSURE

In one aspect, a substrate is disclosed. In one embodiment, the substrate comprises a substrate core including a plurality of through holes located therethrough, a plurality of metal pins aligned in the plurality of through holes, and at least one layer deposited on at least one of top and bottom surfaces of the substrate core. In one embodiment, the plurality of metal pins are aligned with the plurality of through holes such that each of the plurality of metal pins extends at least to both the top and bottom surface of the substate core. In some embodiments, the deposited at least one layer is deposited after the plurality of metal pins have been aligned in the through holes of the substrate core.

In another aspect, a method of manufacturing a substrate is disclosed. In one embodiment, the method comprises forming a plurality of through holes through a substrate core of the substrate, aligning metal pins in each of the plurality of through holes of the substrate core such that each of the metal pins extends at least to both a top and bottom surface of the substrate core, filling each of the plurality of through holes with a resin in an annulus formed between the plurality of through holes and each of the plurality of metal pins, allowing the resin to cure, grinding both sides of the substrate core to allow exposure of the metal pins on both the top and bottom surfaces of the substrate core, fabricating metal pads on the exposed metal pins on both the top and bottom surfaces of the substrate core, and forming at least one layer on the metal pads on at least one of the top and bottom surfaces of the substrate core.

In yet another aspect, an assembled substrate is disclosed. In one embodiment, the assembled substrate comprises a substrate core including a plurality of through holes located therethrough, a plurality of metal pins aligned in the plurality of through holes such that each of the plurality of metal pins extends at least to both a top and bottom surface of the substrate core, at least one layer deposited on at least one of the top and bottom surfaces of the substrate, at least one integrated circuit (IC) affixed to an outermost one of the at least one layer deposited on one side of the substrate core, and a printed circuit board (PCB) affixed to an outermost one of the at least one layer deposited on another side of the substrate core. In one embodiment, the at least one layer is deposited on at least one of the top and bottom surfaces of the substrate core after each of the plurality of metal pins have been aligned in the through holes of the substrate core.

### BRIEF DESCRIPTION OF THE DRAWINGS

Reference is now made to the following descriptions taken in conjunction with the accompanying drawings, in which:

FIG. 1 illustrates a cross section of an example of a substrate having a substrate core after through holes have been drilled according to principles of the disclosure;

FIG. 2 illustrates a cross section of an example of a substrate having a substrate core after metal pins have been placed and aligned in the through holes according to principles of the disclosure;

FIG. 3 illustrates a cross section of an example of a substrate having a substrate core after resin has been placed and cured around the metal pins placed and aligned in the through holes according to principles of the disclosure;

FIG. 4 illustrates a cross section of a substrate having a substrate core after a fixture has been removed, the metal pins have been ground, and pads for the ground ends of the metal pins have been plated according to principles of the disclosure;

FIG. 5 illustrates a cross section of an example of a substrate after insulating layers have been deposited on both sides of a substrate core according to principles of the disclosure;

FIG. 6 illustrates a flow diagram of an example of a method of manufacturing a substrate according to principles of the disclosure;

FIG. 7 illustrates a cross section of an example of an assembled substrate according to principles of the disclosure; and

FIG. 8 illustrates a cross section of a substrate core with magnetic inductors fabricated in through holes of the substrate core according to principles of the disclosure.

### DETAILED DESCRIPTION OF THE DISCLOSURE

As discussed above, several ICs can be mounted to one or both sides of a substrate. The substrate has a substrate core and other layers may be deposited on one or both sides of this substrate core. In many cases, the ICs are affixed to an outermost one of these layers on one (the “IC side”) of the substrate core and a conventional printed circuit board (PCB) is mounted to an outermost one of these layers on an opposite side of the substrate core (the “PCB side”) using conventional means, wherein signals to/from the PCB can pass through the layers of the substrate, including the substrate core, to/from the ICs. The substrate layers typically consist of alternating metal and insulating materials to insulate signal connections between various input/output pads on the ICs and/or PCB. When these signal connections reach the substrate core, electrical connections are made from one side of the substrate core to the other side of the substate core, e.g., from the PCB side of the substrate core to the IC side of the substrate core and vice versa, via plated through holes (PTH). PTHs are fabricated by forming a hole through the substrate core, e.g., a “through hole”, followed by deposition of a plating metal, usually copper (Cu), on a wall of these through holes, leaving a gap in an inner diameter of the through holes. In some embodiments, a thickness of the Cu plated on the walls of the through holes is about 50 μ. This gap is typically then filled with an epoxy resin material.

One reason for the use of the substrate core in a substrate is, as noted above, to prevent warpage of the substrate. Too much warpage of the substrate can lead to reliability issues, particularly for connections to/from the ICs that are affixed to the outermost layer on the IC side of the substrate core or for connections to/from the PCB that is mounted to the outermost layer on the PCB side of the substrate core. Thus, the size of the substate core must increase in the z direction (i.e., the thickness of the substrate core must increase) when the size of the substrate core increases in the x-y direction in order to provide, inter alia, reliable connections for the ICs attached to the outermost layer on the IC side of the substrate. In some embodiments, the substrate core increases in size to about 100 mm×100 mm or 120 mm×120 mm. However, when the thickness of the substrate increases in the z direction, an aspect ratio of the through hole (from one side of the substrate core to the other side of the substrate core) increases, assuming a diameter of the through holes remains the same, where the aspect ratio is a ratio of a thickness of the through hole in the z direction to the diameter of the through hole.

The higher aspect ratio through holes present several challenges with the Cu plating process in the through hole due to the higher aspect ratio of the through holes. Typical trade-offs to reduce these Cu plating process challenges are: (1) increased through hole size (i.e., through hole diameter) to reduce the aspect ratio of the through holes so that a thickness of Cu plating on the walls of the through holes can remain at about 50 μ, which reduces a number of through holes that can be drilled per unit of x-y area (e.g., interconnect density); (2) reduced Cu thickness on the walls below about 50 μ of the higher aspect ratio through holes with normal x-y spacing of the higher aspect ratio through holes, which leads to a reduction of current carrying capacity of the through holes (i.e., reduced Cu thickness for a same amount of current yields higher current density in the Cu plating which impacts electrical performance of the substrate and can cause reliability issues usually through electromigration phenomena), and (3) the use of other materials, e.g., glass, for the substrate core to reduce substrate core thickness and aspect ratio of the through holes and still meet warpage specifications, which presents significant challenges for Cu plating the glass as the ability to plate Cu on the walls of the through holes through glass has not been successfully implemented in large scale manufacture of substrate cores (of particular difficulty is the ability to get Cu seed materials to adhere to the through hole walls of the glass substrate core). In some embodiments, even a Cu plating thickness of about 50 μ is not adequate as the ICs affixed to the substrate require even more current carrying capacity that require an even thicker Cu plating to avoid reliability issue from the higher current, usually causing electromigration concerns.

In some cases, a magnetic inductor is fabricated in some of the through holes (rather than the electrical connections described above). By placing a magnetic inductor in the through hole, there is no need to place the magnetic inductor on a surface of the substrate, thereby reducing the x-y area of the substrate. However, the higher aspect ratio through holes for thicker substrate cores (as described above) presents the same challenges for magnetic inductors in higher aspect through holes as those described above with respect to the electrical connections in the through holes.

This disclosure provides a substrate (and its substrate core) and a method of its manufacture that avoids or at least reduces the above-discussed substrate core higher aspect ratio challenges. The disclosed substrate and its method of manufacture eliminates the need of any plating process in the higher aspect ratio through holes of the substrate core, thereby mitigating the challenges listed above (e.g., both eliminating the need for larger diameter through holes to enable adequate Cu thickness on the inner diameter of the through holes leading to a lower density of through holes in the substrate core, the need for thinner Cu thickness on the inner diameter of a same number of through holes with a same inner diameter leading to poorer electrical and reliability characteristics, and/or an inability to utilize alternative materials for the substrate core (e.g., glass) which could keep the thickness of the core the same).

The disclosed substrate and its method of manufacture eliminates the need of any plating process by placing pre-fabricated metal pins of appropriate diameter aligned with through holes of the substrate core. In some embodiments, a diameter of the metal pins is from about 100 μ to 200 μ. The pre-fabricated metal pins can be comprised of Cu, which will used as a non-limiting example in the disclosure. The disclosed substrate core then has a resin, such as an epoxy-based resin, filled in the through holes in an annulus around the pre-fabricated Cu pins that have been aligned and placed in the through hole. The epoxy-based resin is cured. After the epoxy-based resin has been cured, the disclosed substrate core is ground on both of its sides to allow exposure of the pre-fabricated Cu pins on both sides of the substrate core. Pads can be fabricated on the exposed Cu pins using a conventional lithography plating processes to finish connectivity of the pre-fabricated, pre-aligned Cu pins. Subsequently, conventional layers, as described above, are built up on both sides of the substrate core through a conventional process flow to finish the substrate with the thicker substrate core. With the disclosed substrate and its method of manufacture, thicker substrate cores can be employed with through holes with a same diameter as in thinner substrate cores, thereby maintaining a same interconnect density of the through holes in the substrate core, and electrical performance and reliability can be maintained as the inner diameter of the through holes do not need to be plated.

Since the disclosed substrate and its method of manufacture does not require the need for a plating process, i.e., there is no need to place a Cu seed on a wall of the through holes for Cu plating of the through holes, a glass substrate core can easily be used in place of a glass fiber reinforced epoxy material-based substrate core, e.g., FR4, without the above-described plating process challenges.

Moreover, since the disclosed substate and method of its manufacture does not require the need for a plating process, fabrication of a magnetic inductor in some of the through holes is possible in the higher aspect through holes as the epoxy-based resin can simply be replaced with a magnetic resin material to fabricate the magnetic inductor (and there is no need for the magnetic resin material or magnetic paste to go through a plating bath of a plating process). Alternatively, or in conjunction with the magnetic resin material or magnetic paste, magnetic material pins, rather than pure Cu pins, can be aligned in those through holes targeted to be magnetic inductors. In some embodiments, the magnetic material pins are metal pins, e.g., Cu pins, with a magnetic material (e.g., Invar (FeNi36)) pre-plated on an outer surface of the metal pin. The use of this magnetic resin material or magnetic paste and/or magnetic material pins allows for optimization of magnetic inductor performance without the need to place the magnetic inductor on a surface of the substrate (reducing the x-y area of the substrate).

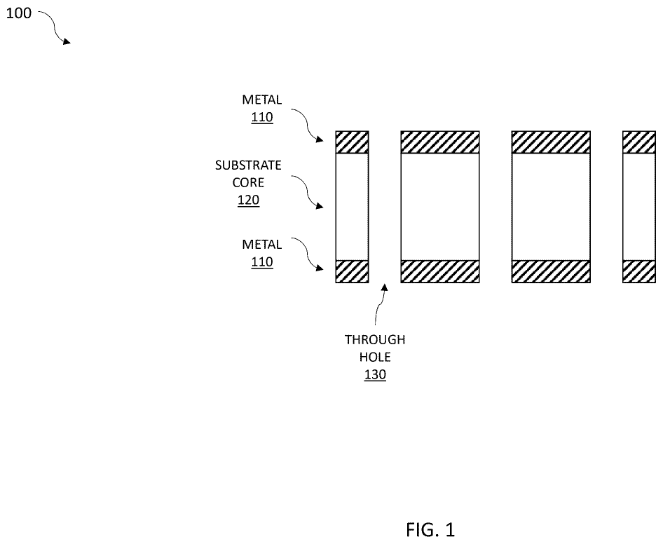

Referring to the drawings, FIGS. 1-4 illustrate various stages of a substrate corresponding to steps of a method of manufacture carried out according to principles of the disclosure. FIG. 1 illustrates a cross section of an example of a substrate 100 having a substrate core 120, be it a glass fiber reinforced epoxy material-based substrate core, e.g., FR-4, or a glass substrate core after through holes 130 have been formed in the substrate core e.g., substrate core 120. For example, in some embodiments, through holes 130 are drilled through a glass fiber reinforced epoxy material-based substrate core (e.g., substrate core 120), e.g., FR-4, or, in other embodiments, through holes 130 are etched through a glass substrate core (e.g., substrate core 120). In many embodiments, a metal layer, e.g., metal layer 110, is formed on both an upper and lower surface of substrate core before through holes 130 have been formed through substrate core 120. In some embodiments, metal layer 120 comprises Cu. While the substrate 100 embodiment of FIG. 1 depicts only three through holes 130, in other embodiments (and for all embodiments depicted in FIGS. 1-7), the substrate can have another number of through holes 130, such as greater than or less than three.

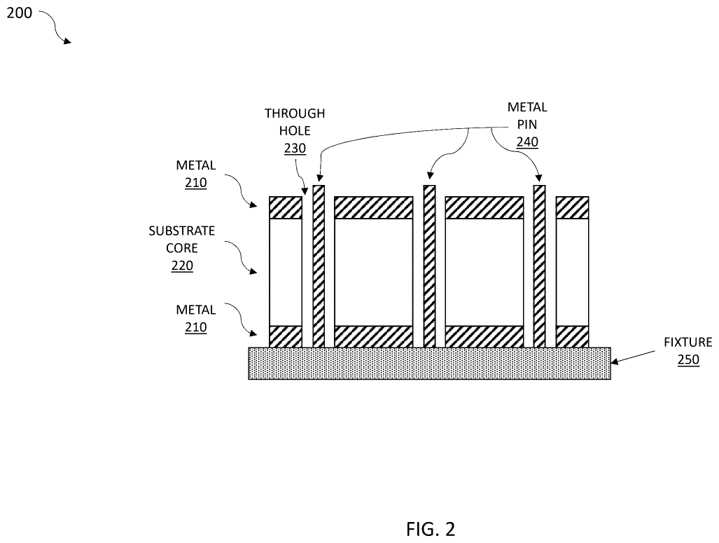

FIG. 2 illustrates ab example of substrate 200 having a substrate core 220 after metal pins have been placed and aligned in the through holes according to principles of the disclosure. Metal pins 240 are pre-placed in fixture 250 at pre-defined positions to correspond with through holes 230 of substrate core 220. As with substrate core 120 of FIG. 1, substrate core 220 can be, in some embodiments a glass fiber reinforced epoxy material-based substrate core, e.g., FR-4, with through holes 230 drilled therethrough at locations that correspond to the position of metal pins 240 affixed to fixture 250 or a glass substrate core with through holes 230 etched therethrough at locations that correspond to the position of metal pins 240 affixed to fixture 250. After metal pins 240 are affixed to fixture 250 at their predetermined locations, substrate core 220 is placed on fixture 250 such that metal pins 240 align within through holes 230. Metal pins 240, is some embodiments, are made of Cu. Furthermore, as with substrate core 120 of FIG. 1, substrate core 220 has metal layer 210 formed on both an upper and lower surface of substrate core 220 before through holes 230 have been formed through substrate core 220. In some embodiments, metal layer 220 comprises Cu and metal layer 210 is formed using conventional techniques. In some embodiments, metal layer 210 is plated on substrate core 220 to a desired thickness and can then be patterned using subtractive patterning methods or semi-additive patterning methods.

In other embodiments, no fixture, e.g., fixture 250, is used and metal pins 240 are formed from metal wires, e.g., Cu wires, that are fed through through holes 230 of substrate core 220. The metal wires can be fed through through holes 230 of substrate core 220 conventionally and conventionally cut to an appropriate length. With no fixture, e.g., fixture 250, used, there is no need to place metal pins, e.g., metal pins 240, in specific locations on the fixture. Again, while the embodiment of substrate 200 of FIG. 2 depicts only three through holes 230 and three metal pins 240, other embodiments (and for all embodiments depicted in FIGS. 1-7), the cross section can have another number of through holes 230 and corresponding metal pins 240.

As disclosed above, metal pins 240 take the place of metal plating conventionally found in plated through holes of a conventional substrate core. By using metal pins 240, plating of through holes 230 is not needed. This allows for the same density of through holes in a thicker substrate core as in a thinner substrate core and also allows for the substrate core to remain thinner when using alternative materials, e.g., glass.

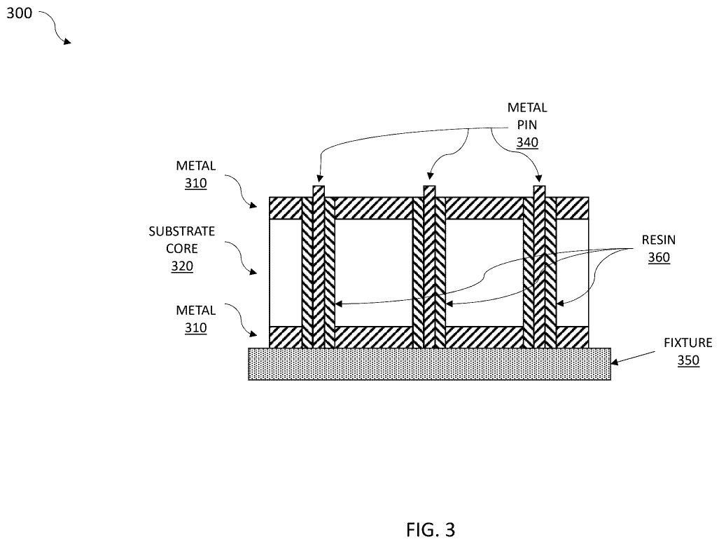

FIG. 3 illustrates a cross section an example of a substrate 300 having a substrate core 320 after resin has been placed and cured around metal pins 340 aligned in the through holes according to principles of the disclosure. As with substrate 200 of FIG. 2, substrate 300 of FIG. 3 depicts fixture 350 with metal pins 340 located in positions such that they correspond to through holes (not labeled) of substrate core 320. In some embodiments, metal pins 340 are pre-assembled and aligned on fixture 350. As with substrate 200 of FIG. 2, substrate 300 of FIG. 3 depicts substrate core 320 (with metal layer 310 formed on both an upper and lower surfaces of substrate core 320) placed over metal pins 340 after metal pins 340 have been affixed to fixture 350.

After substrate core 320 has been placed over metal pins 340, resin 360 is introduced into an annulus around metal pins 340. One purpose of the resin is to make sure metal pins 340 remain in place and adhere to an inner diameter of the through holes (not labeled) of substrate core 320. Different resin materials can be used when substrate core 320 is a glass fiber reinforced epoxy material-based substrate core, e.g., FR-4, than when substrate core 320 is an alternative material, e.g., glass, to ensure that the resin adheres to metal pins 340 and either the glass fiber reinforced epoxy material-based substrate core or the glass core. After the resin 360 has been introduced in the annulus around metal pins 340, resin 360 is cured in a conventional manner based on the specific resin used.

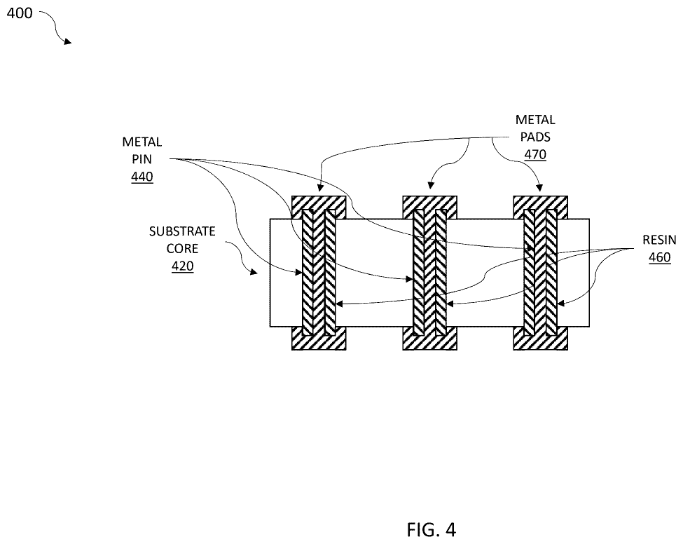

FIG. 4 illustrates a cross section of an example of a substrate 400 having a substrate core 420 after a fixture has been removed, the metal pins have been ground, and pads for the ground ends of the metal pins have been deposited according to principles of the disclosure. In one step, the fixture, e.g., fixture 250 of FIG. 2 and fixture 350 of FIG. 3, is removed from substrate core substrate core 420 (which is similar to substrate core 120 of FIG. 1, substrate core 220 of FIG. 2, and substrate core 320 of FIG. 3). In another step, both the top and bottom surfaces of substrate core 420 are ground to expose top and bottom surfaces of metal pins 440 (similar to metal pins 340 of FIG. 3) and resin 460. Further, the metal layers (e.g., metal layers 110 of FIG. 1, metal layers 210 of FIG. 2, and metal layers 310 of FIG. 3) are removed from both the top and bottom surfaces of substrate core 420 using conventional methods. Lastly metal pads 470 are patterned and deposited over the exposed top and bottom surfaces of both metal pins 440 and resin 460.

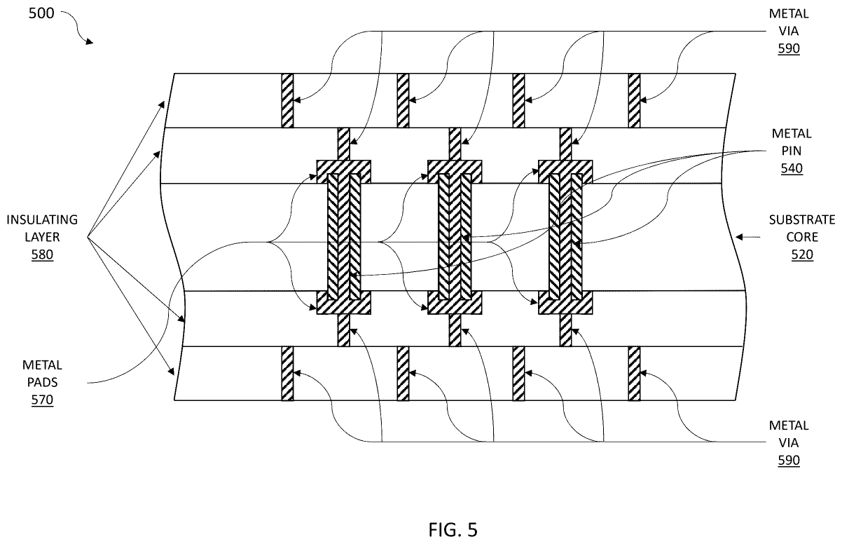

FIG. 5 illustrates a cross section of an example of a substrate 500 after insulating layers have been deposited on both sides of a substrate core 520 according to principles of the disclosure. A portion of the cross section of FIG. 5 is similar to cross section 400 of FIG. 4, e.g., the substrate cores, metal pins, and metal pads. At least one insulating layer, e.g., insulating layer 580, is deposited on one or both sides of substrate core 520 using conventional techniques. After planarization of insulating layers 580, openings are made corresponding to locations where metal interconnects, or metal vias 590, are formed at desired locations. Metal vias 590 provide desired electrical connections from one side of substrate 500 to another side of substrate 500 through substrate core 520 (using metal pins 540 similar to metal pins 240 of FIG. 2, metal pins 340 of FIG. 3, and metal pins 440 of FIG. 4, without any plating of the through holes of substrate core 520 (not labeled) similar to through holes 130 of FIGS. 1 and 230 of FIG. 2). As with metal pads 470 of substrate 400 of FIG. 4, metal pads 570 are patterned and deposited over the exposed top and bottom surfaces of both metal pins (not labeled) and resin (not labeled) and electrically connect to at least some metal vias 590 located in insulating layers 580 directly adjoining substrate core 520.

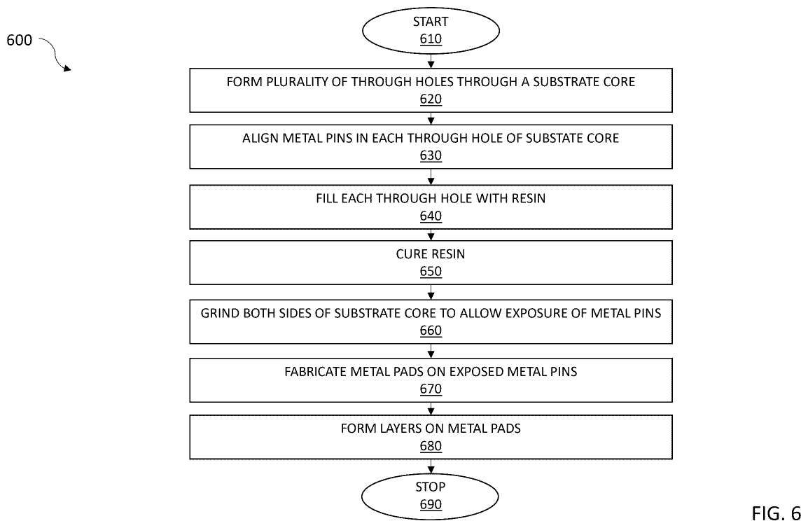

FIG. 6 illustrates a flow diagram of an example of a method 600 of manufacturing a substrate according to principles of the disclosure. The example method 600 of manufacturing a substrate starts at step 610. At step 620, a plurality of through holes are formed through a substrate core. As disclosed above, this plurality of through holes can be formed in a glass fiber reinforced epoxy material, e.g., FR4, substrate core by drilling through the substrate core. The plurality of through holes can also be formed in an alternative material, e.g., glass, by etching through the substrate core. At step 630, metal pins are aligned in each through hole of the substrate core. As disclosed above, in some embodiments these metal pins are pre-assembled and aligned on a fixture or, in other embodiments, these metal pins are formed from metal wire placed in the through holes without a fixture. At step 640, each through hole is filled with a resin material where the resin material used is based on the material of the substrate core (e.g., a glass fiber reinforced epoxy material, e.g., FR4, or glass). At step 650, the resin is cured. As noted above, the resin can be cured in a conventional manner depending on the type of resin.

At step 660, both sides of the substrate core are ground to expose ends of the metal pins. At step 670, metal pads are fabricated on the exposed ends of the metal pins. As step 680, insulating layers are formed on the metal pads, resulting in desired electrical connections from one side of the substrate to the other through the substrate core. The example method 600 of manufacturing a substrate continues to step 690 and ends.

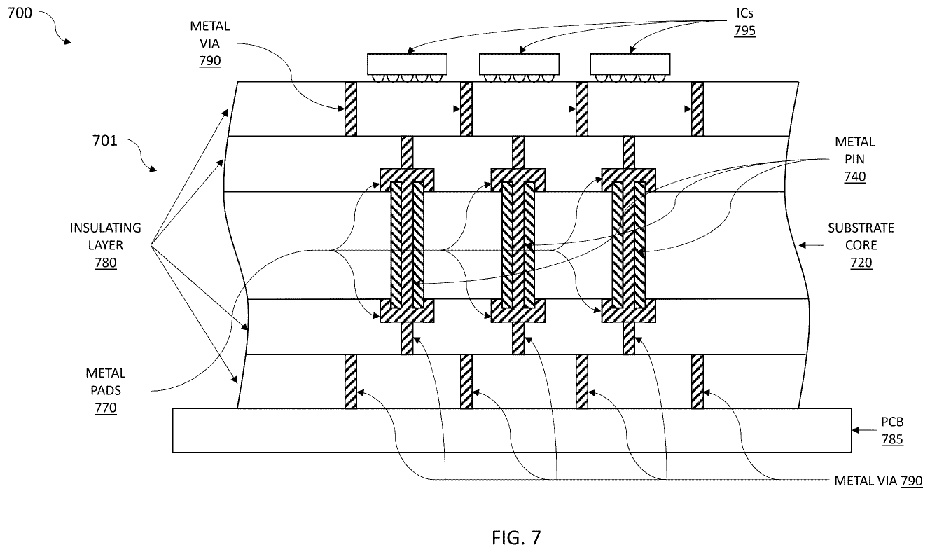

FIG. 7 illustrates a cross section of an example of an assembled substrate 700 having a substrate 701 constructed according to principles of the disclosure. Substrate 701 is similar to substrate 500 illustrated in FIG. 5 above. In addition, assembled substrate 700 includes ICs and a PCB mounted to substrate 701. FIG. 7 illustrates PCB 785 is affixed to substrate 701 (on a “PCB side” of substrate 701, as defined above) and ICs 795 are affixed to substrate 701 on another side (“IC side” of substrate 701, as defined above). In the embodiment of FIG. 7, ICs 795 are bumped and affixed to traces (not shown) on the IC side of substrate 701. Of course, all or some of ICs 795 can be affixed to the IC side of substrate 701 using other means. Assembled substrate 701 includes three ICs 795 affixed to substrate 701. Of course, the number of ICs 795 affixed to substrate 701 can vary more or less than three as depicted in FIG. 7. Furthermore, PCB 785 is affixed to traces (not shown) on the PCB side of substrate 701 using conventional means. Substrate 701 includes two insulating layers 780 between substrate core 720 and PCB 785 and two insulating layers 780 between substrate core 720 and ICs 795. Of course, the number of insulating layers, e.g., insulating layers 780, either between substrate core 720 and PCB 785 or between substrate core 720 and ICs 795 can vary, including zero (i.e., PCB 785 and/or ICs 795 would be affixed directly to substrate 720).

The embodiment of FIG. 7 illustrates a configuration of a substrate core, e.g., substrate core 720, and intervening insulating layers, e.g., insulating layers 780, where electrical signals between PCB 785 and ICs 795 are routed to each other through intervening insulating layers 780 on one side of substrate core 720, metal pins 740 of substrate core 720, and other intervening insulating layers 780 on another side of substrate core 720. The electrical signals traverse through metal pads 770 to metal vias 790 in intervening insulating layers 780 and traces (not shown) on either side of intervening insulating layers 780 between PCB 785 and metal pins 740 of substrate core 720 (similar to metal pins 240 of substrate core 200 of FIG. 2 and metal pins 340 of substrate core 320 of FIG. 3) and through metal pads 770 to metal vias 790 in intervening insulating layers 780 and traces (not shown) on either side of intervening insulating layers 780 between ICs 795 and metal pins 740 of substrate core 720. As disclosed above, the use of these metal pins allows employment of a thicker substrate core, e.g., substrate core 720, to support larger (in the x-y direction) substrate cores without warpage of the substrate core and the elimination of any plating of through holes in the substrate core.

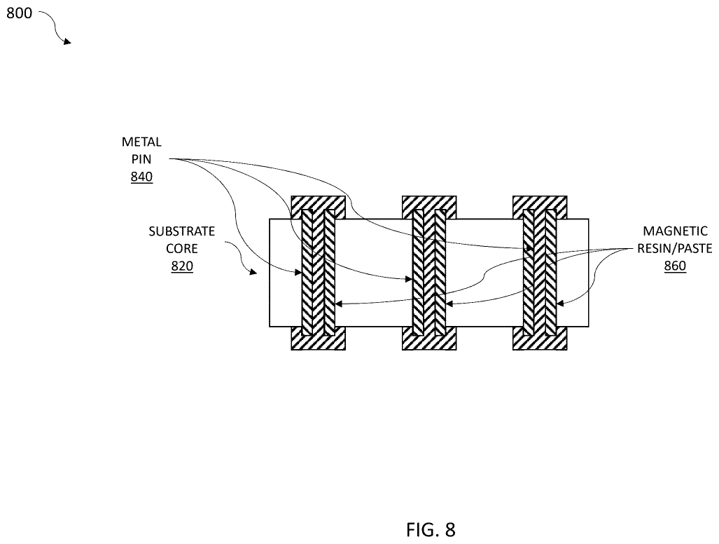

FIG. 8 illustrates a cross section of an example of substrate 800 having substrate core 820 with magnetic inductors fabricated in through holes of the substrate core according to principles of the disclosure. Similar to substrate 400 disclosed in the embodiment of FIG. 4, substrate 800 illustrates magnetic material pins 840 surrounded by magnetic resin/paste 860 in the through holes (not labeled) of substrate core 820 to form magnetic inductors in the through holes. While FIG. 8 depicts all through holes in substrate core 820 contain magnetic inductors, in other embodiments only a desired number of magnetic inductors are fabricated in a subset of the through holes in substrate core 820. In some embodiments, magnetic material pins 840 comprise a Cu pin with a magnetic material (e.g., FeNi36) deposited thereon. In some embodiments, the magnetic material is plated on the Cu pin. In other embodiments, the magnetic material is coated on the Cu using, e.g., physical vapor deposition methods.

In some embodiments, magnetic material pins 840 comprise a Cu plated pin made of a magnetic material. In some embodiments, the magnetic material plated with Cu is a soft magnetic material (e.g., soft ferrites or soft magnetic composites (SMCs)). The type of magnetic material pin and/or type of magnetic resin/paste can be selected to optimize performance of the magnetic inductor. Also, a plurality of magnetic inductors can be interconnected to optimize performance of the inductor.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

What is claimed is:

1. A substrate, comprising:
a substrate core including a plurality of through holes located therethrough;
a plurality of metal pins aligned in the plurality of through holes such that each of the plurality of metal pins extends at least to both a top and bottom surface of the substrate core; and
at least one layer deposited on at least one of the top and bottom surfaces of the substrate core after each of the plurality of metal pins have been aligned in the through holes of the substrate core.

2. The substrate as recited in claim 1, wherein each of the plurality of metal pins comprise copper (Cu).

3. The substrate as recited in claim 1, further comprising resin located in an annulus formed between the plurality of through holes and the plurality of metal pins.

4. The substrate as recited in claim 1, further comprising metal pads fabricated on each exposed end of each of the plurality of metal pins extended to the top and bottom surfaces of the substrate core before the at least one layer is deposited on the at least one of the top and bottom surfaces of the substrate core.

5. The substrate as recited in claim 1, wherein the at least one layer is an insulating layer.

6. The substrate as recited in claim 1, wherein the substrate core comprises a glass fiber reinforced epoxy material.

7. The substrate as recited in claim 6, wherein the glass fiber reinforced epoxy material is FR4.

8. The substrate as recited in claim 1, wherein the substrate core comprises a glass material.

9. The substrate as recited in claim 1, wherein a magnetic inductor is fabricated in at least one of the through holes.

10. The substrate as recited in claim 9, wherein each of the plurality of metal pins is a magnetic material pin, wherein the magnetic material pin comprises a Cu pin with a magnetic material plated thereon to form the magnetic inductor.

11. The substrate as recited in claim 10, wherein the magnetic material plated on the Cu pin is FeNi36.

12. The substrate as recited in claim 10, further comprising a magnetic resin material or magnetic paste located in an annulus formed between the plurality of through holes and each of the plurality of magnetic material pins.

13. A method of manufacturing a substrate, comprising:
forming a plurality of through holes through a substrate core of the substrate;
aligning a plurality of metal pins in each of the plurality of through holes of the substrate core such that each of the plurality of metal pins extends at least to both a top and bottom surface of the substrate core;
filling each of the plurality of through holes with a resin in an annulus formed between the plurality of through holes and each of the plurality of metal pins;
allowing the resin to cure;
grinding both sides of the substrate core to allow exposure of each of the plurality of metal pins on both the top and bottom surfaces of the substrate core;
fabricating metal pads on each exposed end of each of the plurality of metal pins extended to the top and bottom surfaces of the substrate core; and
forming at least one layer on the metal pads on at least one of the top and bottom surfaces of the substrate core.

14. The method of manufacturing a substrate as recited in claim 13, further comprising forming at least one metal via through each of the at least one layer deposited on at least one of the top and bottom surfaces of the substrate core wherein an electrical signal between the at the at least one IC and the PCB is routed through the at least one metal via extended through at least one layer deposited on the one side of the substrate core, metal pads on the one side of the substrate core, at least one of the plurality of metal pins aligned in the plurality of through holes in the substrate core, metal pads on the another side of the substrate core, and the at least one layer deposited on the another side of the substrate core.

15. The method of manufacturing a substrate as recited in claim 14, further comprising forming traces on surfaces of the at least one layer wherein the electrical signal is routed through the traces.

16. The method of manufacturing a substrate as recited in claim 13, wherein the metal pins comprise copper (Cu).

17. The method of manufacturing a substrate as recited in claim 13, wherein the at least one layer is an insulating layer.

18. The method of manufacturing a substrate as recited in claim 13, wherein the substrate core comprises a glass fiber reinforced epoxy material.

19. The method of manufacturing a substrate as recited in claim 18, wherein each of the plurality of through holes is formed by drilling through the glass fiber reinforced epoxy material.

20. The method of manufacturing a substrate as recited in claim 18, wherein the glass fiber reinforced epoxy material is FR4.

21. The method of manufacturing a substrate as recited in claim 13, wherein the substrate core comprises a glass material.

22. The method of manufacturing a substrate as recited in claim 21, wherein each of the plurality of through holes is formed by etching the glass material.

23. The method of manufacturing a substrate as recited in claim 13, further comprising fabricating a magnetic inductor in at least one of the plurality of through holes.

24. The method of manufacturing a substrate as recited in claim 23, wherein each of the plurality of metal pins is a magnetic material pin, wherein each of the magnetic material pins comprises a Cu pin with a magnetic material plated thereon to form the magnetic inductor.

25. The method of manufacturing a substrate as recited in claim 24, wherein the magnetic material plated on the Cu pin is FeNi36.

26. The method of manufacturing a substrate as recited in claim 24, wherein the resin is a magnetic resin material or magnetic paste.

27. An assembled substrate, comprising:
a substrate core including a plurality of through holes located therethrough;
a plurality of metal pins aligned in the plurality of through holes such that each of the plurality of metal pins extends at least to both a top and bottom surface of the substrate core;
at least one layer deposited on at least one of the top and bottom surfaces of the substrate core after each of the plurality of metal pins have been aligned in the through holes of the substrate core;
at least one integrated circuit (IC) affixed to an outermost one of the at least one layer deposited on one side of the substrate core; and
a printed circuit board (PCB) affixed to an outermost one of the at least one layer deposited on another side of the substrate core.

28. The assembled substrate as recited in claim 27, further comprising resin located in an annulus formed between the plurality of through holes and the plurality of metal pins.

29. The assembled substrate as recited in claim 27, wherein each of the plurality of metal pins comprise copper (Cu).

30. The assembled substrate as recited in claim 27, wherein the at least one layer is an insulating layer.

31. The assembled substrate as recited in claim 27, further comprising metal pads fabricated on at least one of an exposed end of each of the plurality of metal pins extended to the top and bottom surfaces of the substrate core before the at least one layer is deposited on the at least one of the top and bottom surfaces of the substrate core.

32. The assembled substrate as recited in claim 31, further comprising at least one metal via extended through each of the at least one layer deposited on at least one of the top and bottom surfaces of the substrate core wherein an electrical signal between the at the at least one IC and the PCB is routed through the at least one metal via extended through at least one layer deposited on the one side of the substrate core, metal pads on the one side of the substrate core, at least one of the plurality of metal pins aligned in the plurality of through holes in the substrate core, metal pads on the another side of the substrate core, and the at least one layer deposited on the another side of the substrate core.

33. The assembled substrate as recited in claim 32, further comprising traces located on surfaces of the at least one layer wherein the electrical signal is routed through the traces.

34. The assembled substrate as recited in claim 27, further comprising fabricating a magnetic inductor in at least one of the plurality of through holes.

35. The assembled substrate as recited in claim 33, wherein each of the plurality of metal pins is a magnetic material pin, wherein each of the magnetic material pins comprises a Cu pin with a magnetic material plated thereon to form the magnetic inductor.

36. The assembled substrate as recited in claim 34, wherein the magnetic material plated on the Cu pin is FeNi36.

37. The assembled substrate as recited in claim 34, wherein the resin is a magnetic resin material or magnetic paste.
